(19) United States
(12) Patent Application Publication
(10) Pub. No.: US 2020/0119212 A1
(43) Pub. Date: Apr. 16, 2020

(54) SOLAR PHOTOELECTRIC PANEL AND AN ASSEMBLING STRUCTURE THEREOF

(71) Applicant: AccelSpirit Inc., Taipei City 106 (TW)

(72) Inventor: Yongxiang Cui, Chengdu (CN)

(21) Appl. No.: 16/653,280

(22) Filed: Oct. 15, 2019

(30) Foreign Application Priority Data
Oct. 15, 2018 (CN) 201821664058.6

(51) Int. Cl. H01L 31/048; H01L 25/04; H02S 20/23

(52) U.S. Cl. CPC H01L 31/048; H02S 20/23; H01L 25/042

(57) ABSTRACT

The present invention is a solar photoelectric panel and an assembling structure of the solar photoelectric panel, the solar photoelectric panel comprises a back plate, a glass plate, and solar cells, the glass plate is provided above the back plate, the solar cells are fixed between the back plate and the glass plate through a plastic film, wherein a fixing part for fixing the solar photoelectric panel at a building is provided by the back plate. The present invention itself is capable of being a building material and the present invention complies with the building functions requirement of heat insulation, waterproof, durable, fireproof, load-bearing, etc.

### CROSS-REFERENCE TO RELATED APPLICATION

This application claims the priority benefit of Chinese Application No. 201821664058.6, filed on Oct. 15, 2018. The entirety of the above-mentioned patent application is hereby incorporated by reference herein and made a part of this specification.

### BACKGROUND OF THE INVENTION

### Field of the Invention

The present invention relates to a building materialized solar photoelectric system, which is waterproof, fireproof and a kind of solar photoelectric capable of bearing weight.

### Background

A structure of a solar photoelectric module in the prior art consists of front panel glass, front EVA plastic film, crystal solar cell, back EVA plastic film and PET back plate assembled and laminated, and then an aluminium alloy frame is added. Therefore a traditional solar photovoltaic module product is created. Generally the traditional solar photovoltaic module product is composed of 60 solar cells or 72 solar cells, and a size of the module products is about 1 meters×1.6 meters, or 1 meters×2 meters, or a form of half-piece, multi-diced/stacked solar cell etc. of an module product with these size bases.

The glass back plate is used for a double glass solar photoelectric module through replacing the PET back plate. A thickness of a front plate glass and a back plate glass is generally 2.5 mm-3.2 mm.

At present, all kinds of integrated solar photovoltaic module products used for building materials still take the main purpose of solar photovoltaic power generation from the product designing, and then how to integrate with existing building is took into account. Wherein said integrated solar photovoltaic module products used for building materials is formed through adjusting a short frame of the traditional module product so as to collocate a water guiding groove under the module through the module product with a frame element overlapped between upper portion and bottom portion. A so-called integrated solar photovoltaic system used for building materials is formed through assembling the existing module technology above the water guiding groove. The existing main application mode is recognized as BIPV products. However, the basic functions required for roof materials of the building including heat insulation, waterproof, durable, fireproof, load-bearing and other basic requirements are not solved by these modified products.

In addition, small tiles made of clay or composite material, each tile is assembled with about 2-6 solar cells to form small-sized solar photovoltaic tiles in order to replace traditional glazed tiles or clay tiles.

However, in actual use, there are several issues resulted from these traditional integrated solar photovoltaic products or system used for building materials: 1. The waterproof effect is not good, i.e., a closed roof structure may be not formed by the assembling method of the traditional module collocated the water guiding groove, and a closed system is not formed from the roof structure system resulting from leakage from a gap between the module and the water guiding groove, therefore the entry of rainwater is not capable of being fundamentally prevented, and it is impossible to prevent moisture from entering the roof. 2. The traditional integrated solar photovoltaic products or system used for building materials are not capable of being applied to large low-slope roofs and versatility is lacked. Small solar photovoltaic tiles is only capable of being used for replacing the roof made of traditional glazed tiles or clay tiles, such roofs have a larger slope (20%-30% above) and is not capable of being collocated general low-slope industrial or commercial roofs (average slopes of 5%-10%). It is difficult to apply to such roofs. The cost is higher, and the installation capacity per square meter is small (30-40 W/m²) such that the guaranteed investment efficiency is difficult to be achieved. 3. The material and structure do not meet fire certification requirements. The back plate of the traditional module is an organic material, and the additional EVA and solar cells are all combustible materials. Therefore there is a cancellation safety concerns when these are installed on the inside of the roof. Such products and roof systems are currently unable to pass the fire acceptance criteria. The same double glass solar photoelectric module is still unable to meet the requirements of fireproof materials because its back plate is glass. 4. The traditional integrated solar photovoltaic products or system used for building materials is unable to bear the weight. A live load generally required by the roof should not less than 30 kg/m², that is, people can walk on the roof so as to maintain the roof such as the live load standard 35 kg/m² required by a color steel tile. However, the traditional module is unable to bear a weight of the person, and only wind load 20 kg/m² is took into account by the uniform load. An internal structure of the module is unable to bear a pressure mankind walking on it. Therefore, it is necessary to install or retain the maintenance passage on the roof, resulting in low utilization of the roof area and causing about 100-120 W/M² of an actual installation capacity per square meter.

A bottom assembling mode is always used by a DC lead-out wire of a conventional solar power generation in the prior art, i.e., a DC circuit is led from a back surface of the solar panel and is connected. All the joints are exposed in the space between the solar panel and the roof, such that a high voltage DC arc is easily formed, and a roof fire is easily caused.

High voltage DC is formed through superimposing dozens of pieces of the solar module of a solar power generation DC lead-out circuit in the prior art, and a DC voltage level reaches two levels of 1000V and/or 1500V, thereby causing the solar panels on the roof to be in a high voltage state. Once a high-voltage connector is loose or detached, it is easy to form a high-voltage DC arc, and a roof fire is easily caused.

With the rapid development of solar photovoltaic dispersion applications and roof-solar photovoltaic integration systems, an improvement technology of the normal module product has been unable to meet the insulation, waterproof, durable, fireproof, load-bearing, etc requirements of current roof. Therefore, it is difficult to meet the requirements of the integrated solar photovoltaic products or system used for building materials.

For example, a double-glass BIPV solar photovoltaic module of the prior art comprises a glass panel, an high light transmitting EVA film, a plurality of solar cells, an anti-ultraviolet EVA film and a back plate superimposed from top to bottom. Said solar cells are uniformly distributed in multiple rows and columns, and a light-transmitting interval is provided between the solar cells. Said technology is sealed by the EVA film, but waterproof and durable thereof is not better than the POE film, and the side connection is inconvenient.

By way of example, a BIPV module of the prior art comprises a front glass, a solar cell and a back glass, overall materials are laminated together into a module, and the solar cells are connected by a solder ribbon. After adding a color or black-and-white plastic plate or plastic film the same as the size and shape of the cell onto the back of each one of the cells, the original gray, solder ribbon and welding surface of the back cell sheet are all covered without being exposed directly. Said technology is also inconvenient to connect with bad waterproof and nondurable.

Further by way of example, a solar photovoltaic tile of the prior art comprises a reinforced glass plate and a solar cell, a raised hem is provided on both sides of the reinforced glass plate, said reinforced glass plate and the two raised hem are an integration structure, and the solar cells in multi rows and columns are provided with an uniform interval above the reinforced glass plate. The solar cells in each row and each column are provided separately. However, there is a connecting end in the said scheme, the connecting end is firmly assembled through ducks, the assembling is not firm enough and not waterproof enough. While the solar cell on two sides of said technology is not sealed by a shell or glue, resulting in short service life and being easy to be destroyed.

### SUMMARY OF THE INVENTION

A solar photoelectric panel which a metal back plate is used to form a roof or wall substrate system covering the exterior of the building and a solar power generation layer is added in order to form a composite material system that a building function is preferentially satisfied while the solar power generation function is fully utilizing, i.e. a photoelectric plate (solar photoelectric panel) used for the building material, the solar photoelectric panel comprising a metal back plate, a glass plate, and a solar cell is provided by the present invention. The glass plate is provided above the backplate, and the solar cells fixed between the back plate and the glass plate through a plastic film, wherein, a fixed part for fixing the solar photoelectric panel at a building is provided by the back plate.

The solar photoelectric panel of the present invention, wherein a quantity of the fixed part is plurality, shapes of the fixed part are W, V or the combination thereof, and the back plate and the fixed part are an overall material and integrated.

The solar photoelectric panel of the present invention, wherein the plastic film is formed by glue after melting sealing, and a plate with a completely and rigidly sealed edge is formed.

The solar photoelectric panel of the present invention, wherein the glue is a clear POE hot-melt adhesive with low vapor transmission rate and high volume resistivity used for replacing traditional EVA packaging materials such that improves the packaging effect.

The solar photoelectric panel of the present invention, wherein a leading wire hole of the solar cell is opened at the back plate.

The solar photoelectric panel of the present invention, wherein the back plate is a metal back plate with a thickness between 0.1 mm and 2 mm, and high rigidity and high strength are provided by the metal back plate, such that it complies with requirements of building materials.

The solar photoelectric panel of the present invention, wherein the back plate is the metal back plate with a thickness between 0.5 mm and 0.6 mm.

The solar photoelectric panel of the present invention, wherein a quantity of the solar cell is a plurality, and a wire layout between the pluralities of solar cells is a net structure.

An assembling structure of the solar photoelectric panel is provided by the present invention. Besides each one of the examples of the solar photoelectric panel as mentioned above, a plurality of the solar photoelectric panel overlapped each other, waterproof cover and self-tapping screw are comprised by the assembling structure of the solar photoelectric panel, wherein the fixed part of the solar photoelectric panel is overlapped by the fixed part of another adjacent solar photoelectric panel, and the self-tapping screw is provided at the overlapped position, therefore the plurality of solar photoelectric panels overlapped each other are fixed at the building through the self-tapping screw.

The assembling structure of the solar photoelectric panel in the present invention, wherein the waterproof cover is independent of the solar photoelectric panel and is made of different colors of metal material.

The assembling structure of the solar photoelectric panel in the present invention, wherein an engagement groove bended inward is provided by the waterproof cover, and a flange extended outward is provided at two sides of the engagement groove, and the engagement groove is provided above the overlapped position of the plurality of fixed parts, the flanges at two sides of the engagement groove are respectively fixed at the glass plate of the plurality of adjacent solar photoelectric panels.

The assembling structure of the solar photoelectric panel in the present invention, wherein an upper leading wire form is used by a DC circuit of the solar photoelectric panel, and wherein a DC circuit leading wire passes through an adjacent hole at a grooved edge of a V shaped fixing part, enters into a closed slot below the waterproof cover, and the upper leading wire form is represented through a closed DC cable slot assembled inside a groove at an overlapped position of a W shaped fixing part and the V shaped fixing part and formed with the waterproof cover, and a voltage of the solar photoelectric panel is always lower than the safety level of 48V through a usage of a safe low voltage technology of the DC circuit of the solar photoelectric panel.

The assembling structure of the solar photoelectric panel in the present invention, wherein a sealing element is further provided between the glass plate and the flange of the waterproof cover. Besides a function of fixing the waterproof cover, a function of sealing is achieved, and entered external rainwater is able to be blocked by the overlapped position.

Compared with the prior art, building materials are able to be used by the present invention self through the back plate and/or the plastic film, etc., and the present invention is fast and easy to install, and building performance requirements of heat-insulated, waterproof, fireproof, durable and load-bearing are complied.

### BRIEF DESCRIPTION OF THE DRAWINGS

FIG. 1 is a top view of the solar photoelectric panel in the present invention.

FIG. 2 is a back view of the solar photoelectric panel in the present invention.

FIG. 3 is a cross-section schematic view of a back plate of the solar photoelectric panel in the present invention.

FIG. 4 is a cross-section partial profile of the solar photoelectric panel in the present invention.

FIG. 5 is an arrangement schematic view of solar cells of the solar photoelectric panel in the present invention.

FIG. 6 is a partial zoom-in schematic view of M in FIG. 5.

FIG. 7 is a schematic view of an assembling structure of the solar photoelectric panel in the present invention.

FIG. 8 is an overlap schematic view of the solar photoelectric panel while assembling in the present invention.

FIG. 9 is a system schematic view of the solar photoelectric panel while the system is used for generating power in the present invention.

### DESCRIPTION OF EMBODIMENTS

The following provides a detailed description of the embodiments along with the accompanied drawings to facilitate the understanding of the technical features and effects of the present invention.

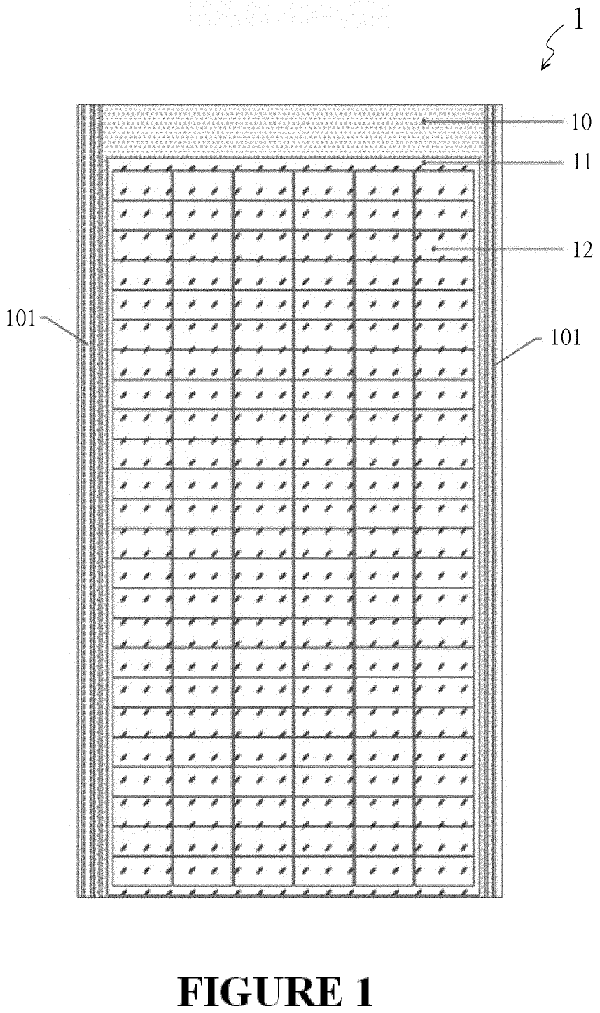

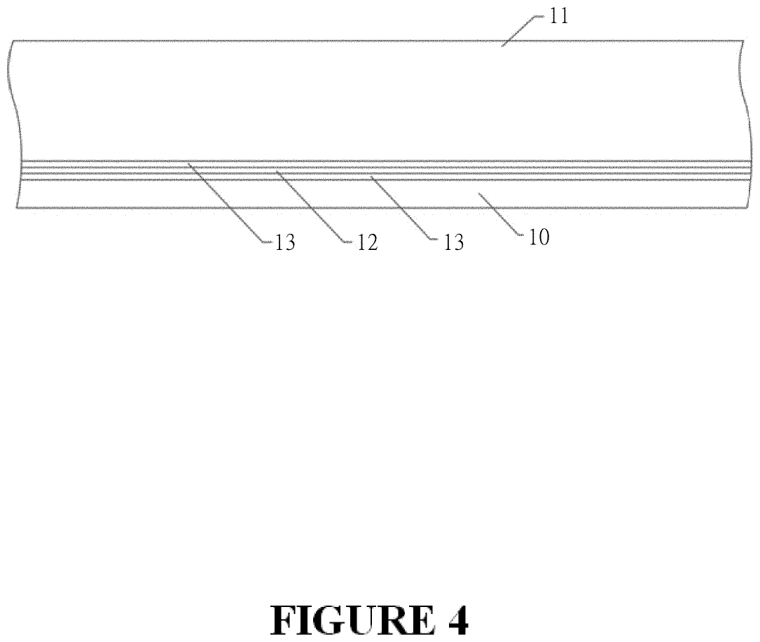

Please refer to FIG. 1, it is a top view of a solar photoelectric panel 1 in the present invention. A back plate 10, a glass plate 11, a solar cell 12 and a plastic film 13 showing in FIG. 4 may be comprised of solar photoelectric panel 1 of the present invention. The back plate 10 as mentioned above may be a metal back plate with a thickness ≤2 mm and ≥0.1 mm in order to bear a most of the range of force applied through the glass plate 11 by an external source, and preferably the back plate 10 may be a metal back with a thickness ≤0.6 mm and ≥0.5 mm in order to bear a normal force applied through the glass plate 11 by an external source. Therefore, a problem of rupture caused by organic materials or a glass used in the prior art, and the glass plate 11 is capable of replacing a color steel tile. Specifically but not limited to, the metal back plate may be an aluminum-zinc alloy coated steel sheet, a zinc-coated steel sheet, a color steel sheet, an aluminum-magnesium alloy sheet, an aluminum alloy sheet, a stainless steel sheet, an aluminum-magnesium-manganese alloy sheet, etc. In addition, a fixing part 101 for fixing the back plate 10 at a building may be provided by the back plate 10. More particularly, shapes of the fixing part 101 may be W, V or the combination thereof, and the back plate 10 and the fixing part 101 may be an overall material and integrated.

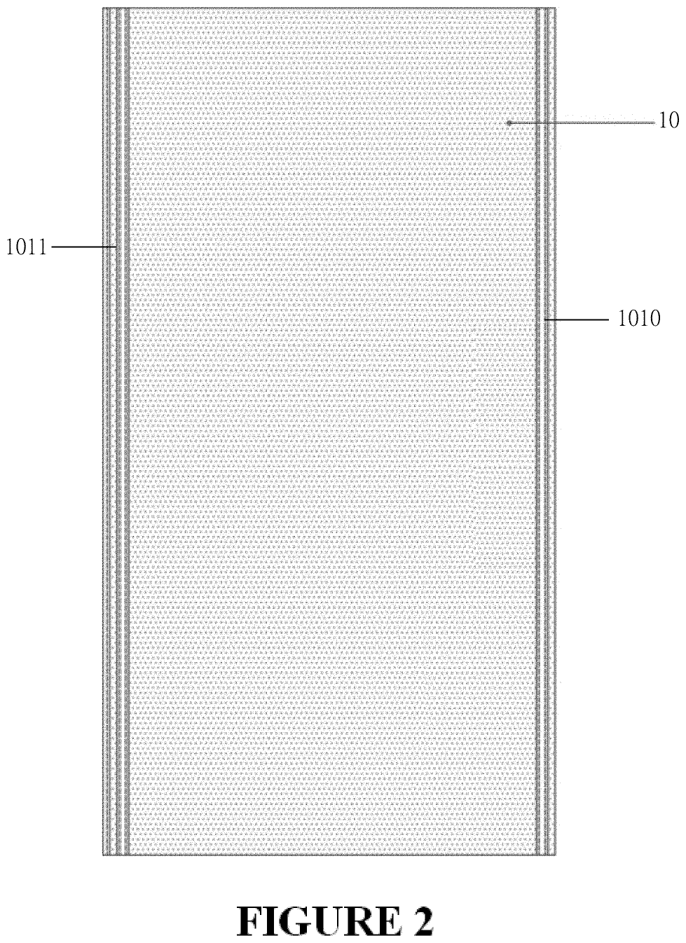

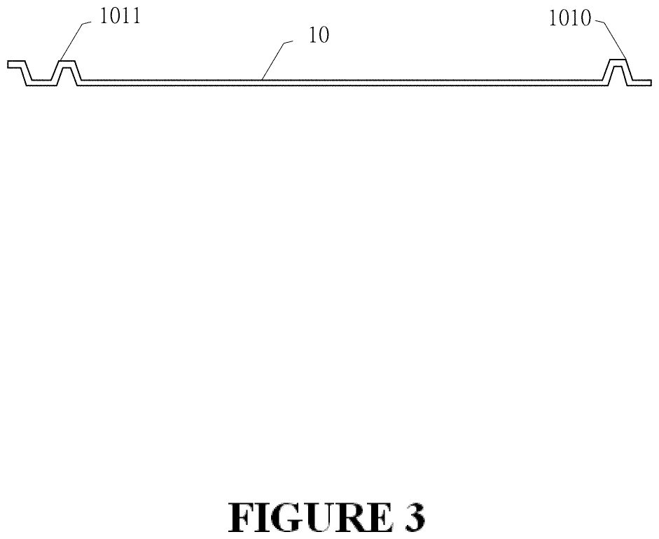

Refer FIG. 2 and FIG. 3 to be an example, a V shaped fixing part 1010 and a W shaped fixing part 1011 may be provided by the opposite two sides of the solar photoelectric panel 1 respectively, but it is not limited in the present invention. For example, the V shaped fixing part 1010 or the W shaped fixing part 1011 may be provided by each one of the sides, or the V shaped fixing part 1010 or the W shaped fixing part 1011 may be provided by the correspondingly opposite two sides respectively. Even more, a U shaped fixing a part or a double-U shaped fixing part may be provided by each one of the sides, or the U shaped fixing part or the double-U shaped fixing part may be provided by the correspondingly opposite two sides respectively, but the shape may be changed with requirement in the present invention. Furthermore, a leading wire hole used for solar cell 12 may be provided by the backplate 10.

The solar cell 12 as mentioned above may be provided on the back plate 10, and the solar cell 12 has opposite top surface and bottom surface, a lateral side connecting the top surface and the bottom surface is provided by the solar cell 12, the bottom surface is positioned on a side of the back plate 10. The solar cell 12 may be a single crystalline-silicon solar cell, a polysilicon solar cell, an amorphous silicon solar cell, a thin film solar cell, a dye sensitized solar cell, a small molecule organic solar cell, a polymer organic solar cell etc. or the combination thereof, but it is not limited in the present invention.

The solar cell 12 as mentioned above may be fixed between the back plate 10 and the glass plate 11 through the plastic film 13. More particularly, the plastic film 13 may extend from the top of top surface of the solar cell 12 and along the lateral side onto a surface of the back plate 10, and a part of the plastic film 13 is positioned between the solar cell 12 and the glass plate 11. Furthermore particularly and showing in FIG. 4, the plastic film 13 may extend along the lateral side and onto the surface of the back plate 10, such that the solar cell 12 is surrounded by the plastic film 13. Or the plastic film 13 may extend along the lateral side and onto a position of the back plate 10 without being covered by the solar cell 12, such that the solar cell 12 is fastened onto the back plate 10 by the plastic film 13. The plastic film 13 may be formed by self-melting glue after sealing, and a plate with a completely and rigidly sealed edge may be formed by the back plate 10, the glass plate 11 and the self-melting glue after the sealing. In the condition that a wire led from the solar cell 12 and through the plastic film 13, a plate with completely and rigidly sealed edge except for an opening connected to the outside may be at least formed by the plastic film 13 and the back plate 10, i.e., the wire of the solar cell 12 may be led to outside through the opening. In addition, the glue may be a clear POE hot-melt Adhesive.

A heat resistant temperature may be increased through performing a crosslinking reaction for POE in the present invention, therefore resulting in a reduced permanent deformation, and resulting in greatly improved tensile strength, tear strength, etc. of major mechanical properties. Good performances such as aging resistant, ozone resistant, chemical resistant, etc. are presented through POE after the crosslinking reaction. The greatest advantages of the POE plastic film are low vapor transmission rate and high volume resistivity, such that the operation safety under high temperature-high humidity and long-term aging resistance of the solar photoelectric panel 1 are proofed, and the solar photoelectric panel 1 is capable of using for at least 25 years. Specifically speaking, the better performance comparing the solar photoelectric panel 1 sealed by POE plastic film to the same sealed by EVA plastic film are 1. The POE plastic film is a copolymer of ethylene and octane and a saturated fat chain structure, carbon atoms are less in the molecular chain. Good weatherability, UV aging resistance, excellent heat resistance, low-temperature resistance, etc., are represented. Therefore a better aging resistance than an EVA plastic film is represented by the POE plastic film. 2. A bonding force between the POE plastic film and material of the glass, the back plate 10, etc. is improved through a modification method such as a photo-grafting polar monomer, plasma surface treatment or reactive graft modification etc., therefore there is a good interface bonding performance in the present invention.

3. The POE plastic film with a lower water vapor transmission rate and a greater cohesive force is more suitable for building-integrated modules. A combination of the glass and the back plate 10 is a research and development result of the present invention, such that the sealed edge is not required and service life is longer in the manufactured building-integrated modules.

Therefore, a POE self-melting sealing processing is used in the present invention, wherein a direct molding is performed in a laminator. A natural integral sealed edge and firm bonding between the glass and the back plate 10 are formed after the POE self-melting sealing.

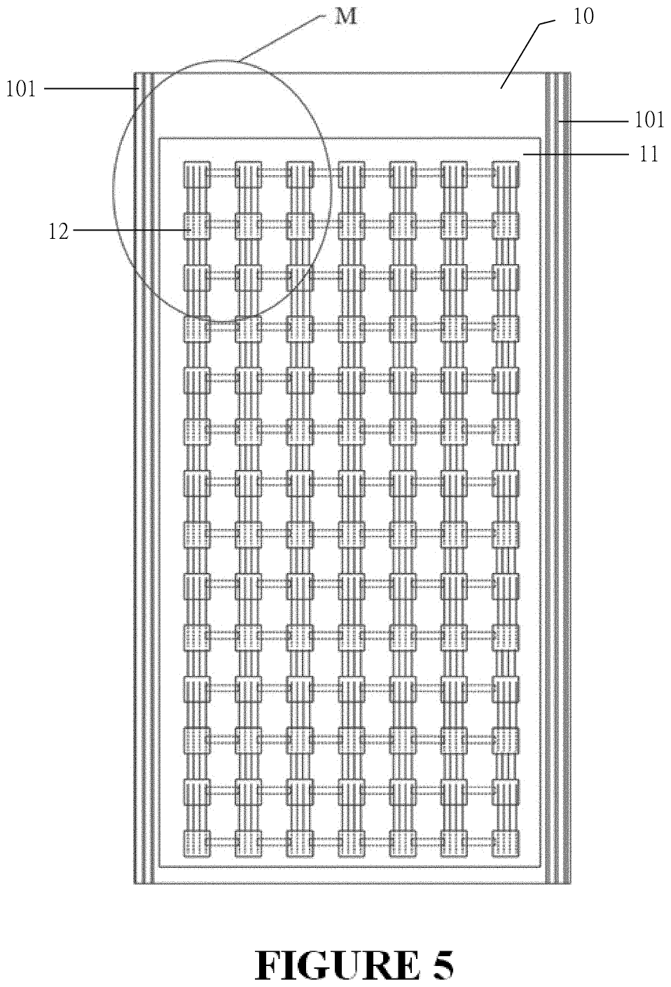

As showing in FIG. 5, if a quantity of the solar cell 12, a wire layout between the pluralities of solar cells 12 is a net structure. Specifically but not limited to, a serial-parallel net structure may be used by the net structure, for example, a parallel circuit is further provided based on a serial circuit. For example, if a rectangle net connection is formed between the pluralities of solar cells 12, except for the solar cell 12 in a corner, each one of the other solar cells 12 are connected to at least three solar cells 12. If the other shaped net connection is formed between the pluralities of solar cells 12, each one of the most solar cells 12 are connected to at least three solar cells 12.

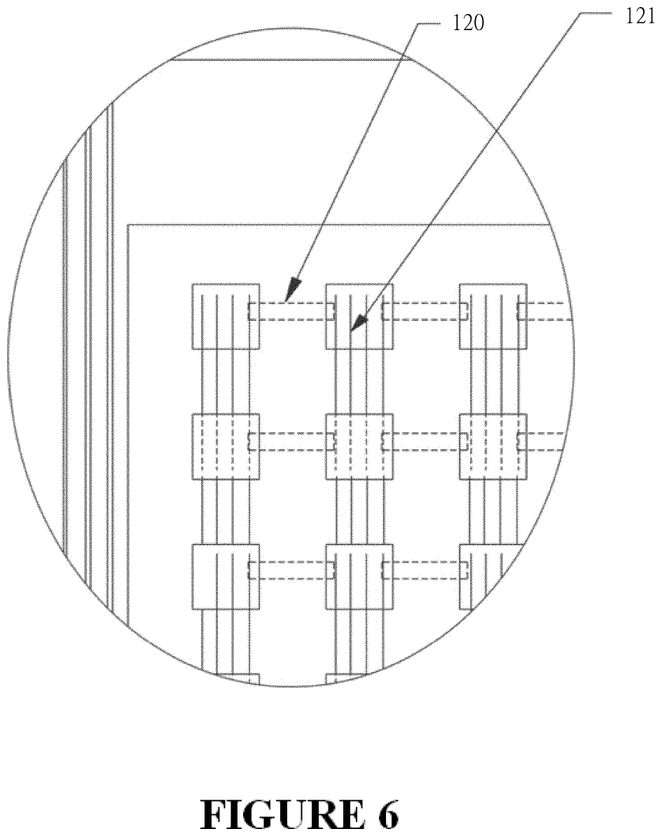

A zoom-in location M as showing in FIG. 5 and a zoom-in FIG. 6 thereof, the plurality of solar cells 12 forming the net connection may be connected by a back connection wire of the cell 120 and/or a front connection wire of the cell 121. A solar cell wire layout of the present invention ensures that there are more than three wires guiding current in the most cells by the usage of the net structure instead of traditional tandem structure wire layout, therefore heating resulted from loading (i.e., hot spot effect) resulted from the shade is prevented.

In addition, the glass plate 11 may be an ultra-clear glass with a transparent nano-coating (this design complies with the ((technical requirements for reduced-reflection coating glass used for crystalline silicon photoelectric elements)), Standard No. SEMI PV47-0513), i.e., self-cleaning and anti-slip high hardness ultra-thin transparent glass, the surface thereof is processed by embossed, reinforced and sprayed nanocoatings at high temperature, i.e., the transmission rate is improved to about 95% and the self-cleaning function and the anti-slip function are presented. The glass plate 11 of the present invention is not an embossed ultra-transparent glass used for the solar module in the prior art. Therefore the following effect is representing by the usage of the glass plate 11 in the present invention: 1. improved transmission rate, the transmission rate of the ultra-clear glass is increased by 3% to 5% with nano-scale optical coating technology, therefore an output power of the solar photoelectric panel 1 is improved, 2. a strong self-cleaning function, good appearance for a long time and a self-cleaning effect for a long time may be maintained by a nano-scale inorganic silicon oxide coating, and a manual cleaning is not required due to an ultra-hydrophilic feature, i.e., a pollution is fallen off in the raining condition by the rainwater self-washing, 3. an improved scratch-resistant hardness, 3H anti-scratch effect hardness may be achieved after strengthening, 4. coating layer with high chemical stability, high thermal stability, high-temperature variation resistance, aging resistance, acid, and alkali corrosion resistance provides the solar glass to still maintain stable improved clear and anti-pollution performance for a long time in the outdoor application.

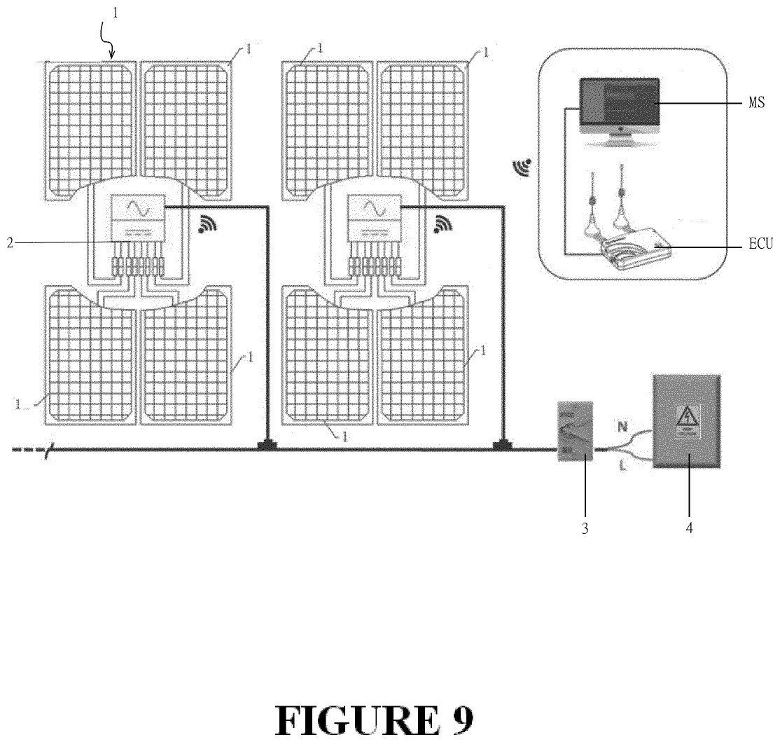

Furthermore, an AC/DC conversion controller 2 (in FIG. 9) is comprised by the solar photoelectric panel 1, the AC/DC conversion controller 2 is connected to the solar cell 12 or the module thereof, in order to convert AC to DC for generating the power.

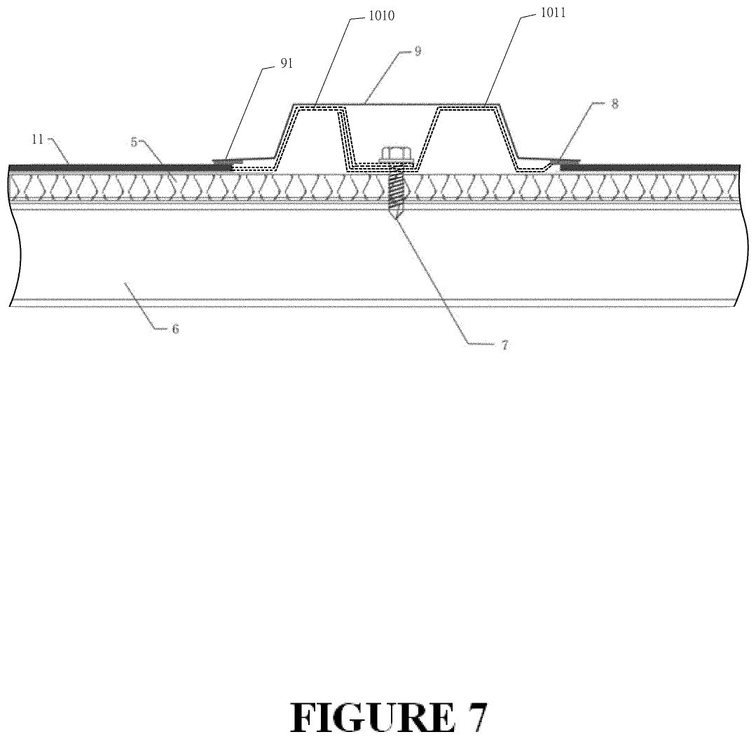

Another assembling structure of the solar photoelectric panel is provided by the present invention. As showing in FIG. 7 and referring to FIG. 1 to FIG. 6, a plurality of the solar photoelectric panel 1 overlapped each other, a waterproof cover 9 and a self-tapping screw 7 are comprised of the assembling structure of the solar photoelectric panel. Wherein the fixed part 101 of the solar photoelectric panel 1 is overlapped by the adjacent fixed part 101 of solar photoelectric panel 1, and the self-tapping screw 7 is provided at the overlapped position. The plurality of solar photoelectric panels overlapped each other are fixed at the building 6 through the self-tapping screw 7. The other detailed content of the solar photoelectric panel 1 is described above, no longer to repeat. For example, a position of the building 6 the solar photoelectric panel 1 is fixed may be a purlin structure (also known as a purline, a ridgepole, a purlin, a girder, or a “tuán” called in the Tang and Song Dynasties) of a roof surface, but it is not limited in the present invention. In addition, when the solar photoelectric panel of the present invention is assembled, it is only required to perform assembling with single construction surface and standing on the roof through the usage of a connection between the self-tapping screw and the purline of the roof surface instead of ducks mounting or penetrating bolt connection.

In particular but not limited to, an engagement groove bent inward is provided by the waterproof cover 9, and a flange 91 extending outward is provided at two sides of the engagement groove. The engagement groove is provided above the overlapped position of the plurality of fixed parts 101, and the flanges 91 at two sides of the engagement groove are respectively fixed at the glass plate 11 of the plurality of adjacent solar photoelectric panels 1. Furthermore, the waterproof cover 9 may be independent of the solar photoelectric panel 1 so as to be replaced and may be made of different colors of various materials or different colors of metal material so as to form an appearance characteristics of the colorful roof. Due to a convenient form of transformation, additional more colors and architectural features are provided to the roof.

More particular but not limited to, if at least one W shaped and at least one V shaped fixing parts 101 (i.e., V shaped fixing part 1010 and W shaped fixing part 1011) are provided to each of the solar photoelectric panel 1, V shaped fixing part 1010 and W shaped fixing part 1011 of the two respective adjacent solar photoelectric panels 1 are overlapped each other. The two overlapped fixing parts 101 are penetrated by the self-tapping screw 7, and an engagement groove bent inward is provided to the waterproof cover 9. The flanges 91 extended outward are provided at the two sides of the engagement groove, and the engagement groove is assembled above the two overlapped fixing parts 101. The flanges 91 at the two sides of the engagement groove are fixed at the glass plates 11 of the two adjacent solar photoelectric panels 1 respectively. In addition, a sealing element 8 is further provided between the glass plate 11 and the flange 91 of the waterproof cover 9.

Specifically but not limited to, an upper leading wire form is used based on a DC circuit leading wire of the solar power generation passing through an adjacent hole at an edge of a V shaped fixing part 1010 and then entering into a closed slot below the waterproof cover 9, and the upper leading wire form is represented through a closed DC cable slot assembled inside a groove at an overlapped position of a W shaped fixing part 1011 and the V shaped fixing part 1010 and formed with the waterproof cover 9.

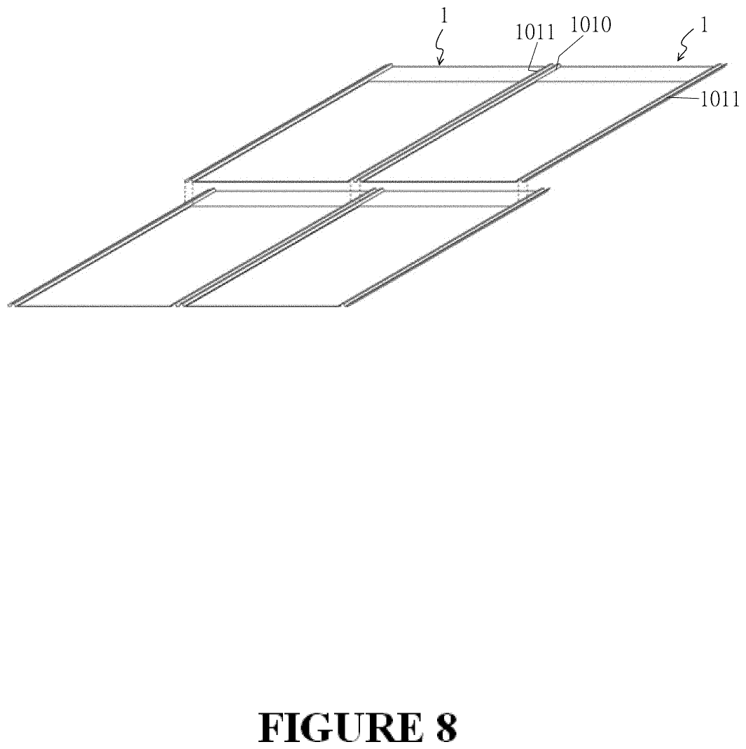

As showing in FIG. 8, the plurality of solar photoelectric panels 1 may form a solar power generation structure assembled at the building by the V shaped fixing part 1010 and W shaped fixing part 1011 overlapped each other.

Therefore, effects of simple and reliable waterproof, easily assembling and using and easily replacing, etc., in the present invention are represented by a usage of V shaped and W shaped pressed molding and vertical edge.

In addition, after the vertical V shaped frame is overlapped onto the W shaped frame of the solar photoelectric panel 1, the top of the V shaped frame and the W shaped frame is covered by the waterproof cover 9. A transverse upper plate and lower plate are directly overlapped. A sealing element 8 is used at two sides under the waterproof cover 9. The waterproof cover 9 is overlapped onto the glass plate, and a sealing element 8 is used at the overlapped position. After the solar photoelectric panel 1 is assembled, only the self-cleaning and anti-slip high hardness ultra-thin transparent glass surface and the waterproof cover 9 are represented on the building outside surface. It significantly improves weather resistance, self-cleaning performance, sealing performance, waterproof performance, smooth flow of rainwater, etc. of the solar photoelectric panel 1.

Furthermore, there may be an insulated cotton 5 between the solar photoelectric panel 1 and building 6.

A roof rainwater collecting unit or a system thereof may be further provided to the assembling structure of the solar photoelectric panel in the present invention in order to realize an automatic collection of rainwater.

A roof automatic spray unit or a system thereof may be further provided to the assembling structure of the solar photoelectric panel in the present invention in order to cool the roof, clean the glass surface, enhance the power generation capacity and realizes the intelligent cooling function through controlling the temperature detection to the lower space of the roof and automatically starting the roof spray unit or a system thereof.

As showing in FIG. 9, the AC/DC conversion controller 2 may be shared by the plurality of solar photoelectric panels 1, and the AC/DC conversion controller 2 may be monitored by a monitoring system MS through an energy communication unit ECU in a wired or wireless method. In addition, the solar photoelectric panel 1 may be connected to an AC isolator 3, and the AC isolator 3 may be connected to a distribution box 4.

By way of example and not limitation, after an usage of the solar photoelectric panel 1 collocated a micro AC/DC conversion controller 2, a traditional color steel tile may be replaced by the solar photoelectric panel 1, and a solar photoelectric power generation function with the solar photoelectric panel 1 may be represented. A direct current with less than a safe DC voltage 48V is generated through a solar cell coupled to a front layer of the solar photoelectric panel 1, and the direct current is converted into a 220V alternating current by the micro AC/DC conversion controller 2 collocated the solar photoelectric panel 1. Or a 380V AC is collected and grouped phase through 220V single-phase AC mentioned above, and the 380V AC is coupled to an internal power system of the building in order to achieve a power generation function. In addition, a safe low voltage technology is used for the DC circuit of the solar power generation panel. Therefore a voltage of the solar photoelectric panel 1 is always lower than the safety level of 48V.

In conclusion, at least the function of improving the load-bearing for building materials and durable is represented by the back plate of the present invention. In addition, the effects of aging resistant, ozone resistance, and chemical resistance are further represented by the sealed plastic film of the present invention. Furthermore, the loading heat resulted from the shade is further prevented by the present invention, and effects of maintaining stable anti-pollution performance, easily assembling, simple and reliable waterproof, easily assembling and using, easily replacing, smooth flow of rain, etc. are provided by the present invention.

The above describes the preferred embodiments of the present invention. However, not all of the elements or steps are essential technical features, and all details of the technical features may not have been described completely. All units and steps described are provided as examples only, and they may be modified by a person ordinarily skilled in the art of the technical field of this patent application. The scope of the present invention shall be defined by the claims thereof.

What is claimed is:

1. A solar photoelectric panel, comprising:
a back plate;
a glass plate provided above the back plate; and
solar cells fixed between the back plate and the glass plate through a plastic film;
wherein a fixing part for fixing the solar photoelectric panel at a building is provided by the back plate.

2. The solar photoelectric panel according to claim 1, wherein a quantity of the fixing part is a plurality, shapes of the fixing part are W, V or the combination thereof, and the back plate and the fixing part are an overall material and integrated.

3. The solar photoelectric panel according to claim 1, wherein the plastic film is formed by self-melting glue after sealing, and a plate with a completely and rigidly sealed edge is formed.

4. The solar photoelectric panel according to claim 3, wherein the glue is a clear POE hot-melt adhesive.

5. The solar photoelectric panel according to claim 3, wherein a leading wire hole of the solar cell is opened at the back plate.

6. The solar photoelectric panel according to claim 1, wherein the back plate is a metal back plate with a thickness between 0.1 mm and 2 mm.

7. The solar photoelectric panel according to claim 6, wherein the back plate is the metal back plate with a thickness between 0.5 mm and 0.6 mm.

8. The solar photoelectric panel according to claim 1, wherein a quantity of the solar cell is a plurality, and a wire layout between the plurality of solar cells is a net structure.

9. An assembling structure of the solar photoelectric panel according to one of claim 1, wherein the assembling structure of the solar photoelectric panel comprises a plurality of the solar photoelectric panel overlapped each other, a waterproof cover and a self-tapping screw, wherein the fixing part of the solar photoelectric panel is overlapped by the fixing part of another adjacent solar photoelectric panel, and the self-tapping screw is provided at the overlapped position, therefore the plurality of solar photoelectric panels overlapped each other are fixed at the building through the self-tapping screw.

10. The assembling structure of the solar photoelectric panel according to claim 8, wherein the waterproof cover is independent of the solar photoelectric panel, and is made of different colors of metal material.

11. The assembling structure of the solar photoelectric panel according to claim 9, wherein an engagement groove bent inward is provided by the waterproof cover, and a flange extended outward is provided at two sides of the engagement groove, and the engagement groove is provided above the overlapped position of the plurality of fixing parts, the flanges at two sides of the engagement groove are respectively fixed at the glass plate of the plurality of adjacent solar photoelectric panels.

12. The assembling structure of the solar photoelectric panel according to claim 9, wherein an upper leading wire form is used by a DC circuit of the solar photoelectric panel, and wherein a DC circuit leading wire passes through an adjacent hole at a groove edge of a V shaped fixing part, enters into a closed slot below the waterproof cover, and the upper leading wire form is represented through a closed DC cable slot assembled inside a groove at an overlapped position of a W shaped fixing part and the V shaped fixing part and formed with the waterproof cover, and a voltage of the solar photoelectric panel is always lower than the safety level of 48V through a usage of a safe low voltage technology of the DC circuit of the solar photoelectric panel.

13. The assembling structure of the solar photoelectric panel according to claim 9, wherein a sealing element is further provided between the glass plate and the flange of the waterproof cover.

14. An assembling structure of the solar photoelectric panel according to one of claim 2, wherein the assembling structure of the solar photoelectric panel comprises a plurality of the solar photoelectric panel overlapped each other, a waterproof cover and a self-tapping screw, wherein the fixing part of the solar photoelectric panel is overlapped by the fixing part of another adjacent solar photoelectric panel, and the self-tapping screw is provided at the overlapped position, therefore the plurality of solar photoelectric panels overlapped each other are fixed at the building through the self-tapping screw.

15. An assembling structure of the solar photoelectric panel according to one of claim 3, wherein the assembling structure of the solar photoelectric panel comprises a plurality of the solar photoelectric panel overlapped each other, a waterproof cover and a self-tapping screw, wherein the fixing part of the solar photoelectric panel is overlapped by the fixing part of another adjacent solar photoelectric panel, and the self-tapping screw is provided at the overlapped position, therefore the plurality of solar photoelectric panels overlapped each other are fixed at the building through the self-tapping screw.

16. An assembling structure of the solar photoelectric panel according to one of claim 4, wherein the assembling structure of the solar photoelectric panel comprises a plurality of the solar photoelectric panel overlapped each other, a waterproof cover and a self-tapping screw, wherein the fixing part of the solar photoelectric panel is overlapped by the fixing part of another adjacent solar photoelectric panel, and the self-tapping screw is provided at the overlapped position, therefore the plurality of solar photoelectric panels overlapped each other are fixed at the building through the self-tapping screw.

17. An assembling structure of the solar photoelectric panel according to one of claim 5, wherein the assembling structure of the solar photoelectric panel comprises a plurality of the solar photoelectric panel overlapped each other, a waterproof cover and a self-tapping screw, wherein the fixing part of the solar photoelectric panel is overlapped by the fixing part of another adjacent solar photoelectric panel, and the self-tapping screw is provided at the overlapped position, therefore the plurality of solar photoelectric panels overlapped each other are fixed at the building through the self-tapping screw.

18. An assembling structure of the solar photoelectric panel according to one of claim 6, wherein the assembling structure of the solar photoelectric panel comprises a plurality of the solar photoelectric panel overlapped each other, a waterproof cover and a self-tapping screw, wherein the fixing part of the solar photoelectric panel is overlapped by the fixing part of another adjacent solar photoelectric panel, and the self-tapping screw is provided at the overlapped position, therefore the plurality of solar photoelectric panels overlapped each other are fixed at the building through the self-tapping screw.

19. An assembling structure of the solar photoelectric panel according to one of claim 7, wherein the assembling structure of the solar photoelectric panel comprises a plurality of the solar photoelectric panel overlapped each other, a waterproof cover and a self-tapping screw, wherein the fixing part of the solar photoelectric panel is overlapped by the fixing part of another adjacent solar photoelectric panel, and the self-tapping screw is provided at the overlapped position, therefore the plurality of solar photoelectric panels overlapped each other are fixed at the building through the self-tapping screw.

20. An assembling structure of the solar photoelectric panel according to one of claim 8, wherein the assembling structure of the solar photoelectric panel comprises a plurality of the solar photoelectric panel overlapped each other, a waterproof cover and a self-tapping screw, wherein the fixing part of the solar photoelectric panel is overlapped by the fixing part of another adjacent solar photoelectric panel, and the self-tapping screw is provided at the overlapped position, therefore the plurality of solar photoelectric panels overlapped each other are fixed at the building through the self-tapping screw.
